(19) United States
(12) Patent Application Publication
(10) Pub. No.: US 2023/0422526 A1
(43) Pub. Date: Dec. 28, 2023

(54) SEMICONDUCTOR PACKAGE STRUCTURE

(71) Applicant: MediaTek Singapore Pte. Ltd., Singapore (SG)

(72) Inventors: Chang LIANG, Singapore (SG); Zhigang DUAN, Singapore (SG); Duen-Yi HO, Hsinchu City (TW); Yi-Jyun LEE, Hsinchu City (TW)

(21) Appl. No.: 18/320,425

(22) Filed: May 19, 2023

Related U.S. Application Data
(60) Provisional application No. 63/354,374, filed on Jun. 22, 2022.

(51) Int. Cl. H10B 80/00; H01L 25/16; H01L 23/31

(52) U.S. Cl. CPC H10B 80/00; H01L 23/3157; H01L 25/16

(57) ABSTRACT

A semiconductor package structure includes a dynamic random access memory (DRAM) die, a capacitor die, and a molding material. The capacitor die is disposed below the DRAM die and includes a plurality of capacitor structures and a plurality of first conductive pillars. The capacitor structures are arranged side-by-side. The first conductive pillars are disposed over the capacitor structures and are electrically coupled to the DRAM die. The molding material surrounds the capacitor die and the DRAM die.

### CROSS REFERENCE TO RELATED APPLICATIONS

This application claims the benefit of U.S. Provisional Application No. 63/354,374 filed on Jun. 22, 2022, the entirety of which is incorporated by reference herein.

### BACKGROUND OF THE INVENTION

### Field of the Invention

The present invention is related to semiconductor technology, and in particular to a semiconductor package structure including capacitor structures.

### Description of the Related Art

Semiconductor package structures are widely used in various electronic applications, such as personal computers, mobile phones, digital cameras, and other electronic equipment. As a result of the progress being made in the semiconductor industry, a smaller semiconductor package structure that takes up less space than the previous generation of semiconductor package structures is required.

In addition, as high-performance integrated circuits demand larger currents at higher frequencies with lower power-supply voltages, power system design has become increasingly challenging. Decoupling capacitors may be adopted to act as temporary charge reservoirs to prevent momentary fluctuations in supply voltage. The decoupling capacitors are more and more important in reducing power noise.

However, although existing semiconductor package structures generally meet requirements, they have not been satisfactory in every respect. For example, while the size of electronic components such as transistors and resistors is getting smaller, capacitor structures still need to take up more space than other electronic components owing to their physical properties. This makes the miniaturization of semiconductor package structures more difficult. Therefore, further improvements to semiconductor package structures are required.

### BRIEF SUMMARY OF THE INVENTION

Semiconductor package structures are provided. An exemplary embodiment of a semiconductor package structure includes a dynamic random access memory (DRAM) die, a capacitor die, and a molding material. The capacitor die is disposed below the DRAM die and includes a plurality of capacitor structures and a plurality of first conductive pillars. The capacitor structures are arranged side-by-side. The first conductive pillars are disposed over the capacitor structures and are electrically coupled to the DRAM die. The molding material surrounds the capacitor die and the DRAM die.

Another exemplary embodiment of a semiconductor package structure includes a substrate, a capacitor die, a dynamic random access memory (DRAM) die, a first molding material, and a semiconductor die. The substrate includes a wiring structure. The capacitor die is disposed over the substrate and includes a plurality of capacitor structures. The DRAM die is stacked over and is electrically coupled to the capacitor die. The first molding material is disposed over the substrate and surrounds the capacitor die and the DRAM die. The semiconductor die is electrically coupled to the capacitor die and the DRAM die through the wiring structure of the substrate.

Yet another exemplary embodiment of a semiconductor package structure includes a first package structure and a second package structure. The first package structure includes a semiconductor die. The second package structure is stacked over the first package structure and includes a substrate, a capacitor die, and a first dynamic random access memory (DRAM) die. The capacitor die is disposed over the substrate and is electrically coupled to the semiconductor die. The capacitor die includes a plurality of capacitor structures arranged side-by-side. The first DRAM die is electrically coupled to the semiconductor die through the capacitor die.

### BRIEF DESCRIPTION OF THE DRAWINGS

The present invention can be more fully understood by reading the subsequent detailed description and examples with references made to the accompanying drawings, wherein:

FIGS. 1-5 are cross-sectional views of exemplary semiconductor package structures in accordance with some embodiments.

### DETAILED DESCRIPTION OF THE INVENTION

The following description is made for the purpose of illustrating the general principles of the invention and should not be taken in a limiting sense. The scope of the invention is best determined by reference to the appended claims.

The present disclosure will be described with respect to particular embodiments and with reference to certain drawings, but the disclosure is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the disclosure.

Additional elements may be added on the basis of the embodiments described below. For example, the description of “a first element on/over a second element” may include embodiments in which the first element is in direct contact with the second element, and may also include embodiments in which additional elements are disposed between the first element and the second element such that the first element and the second element are not in direct contact.

Furthermore, the description of “a first element extending through a second element” may include embodiments in which the first element is disposed in the second element and extends from a side of the second element to an opposite side of the second element, wherein a surface of the first element may be substantially leveled with a surface of the second element, or a surface of the first element may be outside a surface of the second element.

The spatially relative descriptors of the first element and the second element may change as the structure is operated or used in different orientations. In addition, the present disclosure may repeat reference numerals and/or letters in the various embodiments. This repetition is for simplicity and clarity and does not in itself dictate a relationship between the various embodiments discussed.

A semiconductor package structure including capacitor structures is described in accordance with some embodiments of the present disclosure. The semiconductor package structure includes a capacitor die and one or more DRAM dies which are integrated, wherein the capacitor die includes capacitor structures. As a result, the capacitance can be increased without taking up larger areas.

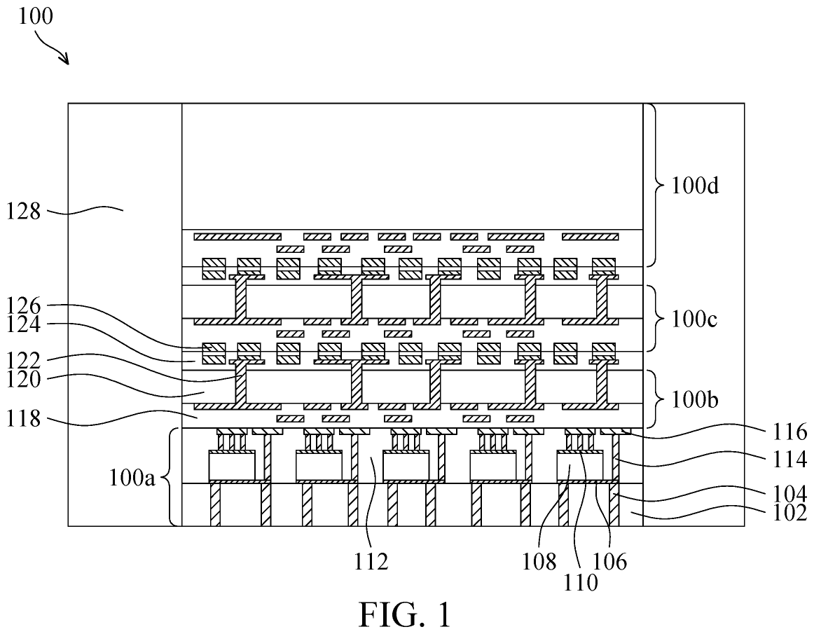

FIG. 1 is a cross-sectional view of a semiconductor package structure 100 in accordance with some embodiments of the present disclosure. Additional features can be added to the semiconductor package structure 100. Some of the features described below can be replaced or eliminated for different embodiments. To simplify the diagram, only a portion of the semiconductor package structure 100 is illustrated.

As shown in FIG. 1, the semiconductor package structure 100 includes a capacitor die 100a and DRAM dies 100b, 100c, 100d which are stacked vertically, in accordance with some embodiments. Therefore, some of land-side capacitors and/or die-side capacitors can be omitted, thereby improving the design flexibility. In addition, the capacitance of the semiconductor package structure 100 can be increased without taking up larger areas.

As illustrated in FIG. 1, the capacitor die 100a includes a semiconductor substrate 102, in accordance with some embodiments. The semiconductor substrate 102 may be formed of any suitable semiconductor material, such as silicon, germanium, silicon carbon, silicon germanium, gallium arsenide, indium arsenide, indium phosphide, the like, or a combination thereof. The semiconductor substrate 102 may include a bulk semiconductor or a composite substrate formed of different materials. The semiconductor substrate 102 may include a semiconductor-on-insulator (SOI) substrate formed by a semiconductor material on an insulating layer, such as a silicon-on-insulator substrate, the germanium-on-insulator, the like, or a combination thereof.

The semiconductor substrate 102 may be doped (e.g., using p-type or n-type dopants) or undoped. Any desired semiconductor elements (including active elements and/or passive elements) may be formed in and on the semiconductor substrate 102. However, in order to simplify the figures, only the flat semiconductor substrate 102 is illustrated.

As shown in FIG. 1, the capacitor die 100a includes a plurality of capacitor structures disposed over the semiconductor substrate 102, in accordance with some embodiments. The capacitor structures may include top-up type capacitor structures. Each of the capacitor structures may include a first electrode layer 106, capacitor cells 108, and a second electrode layer 110, wherein the capacitor cells 108 may be disposed between the first electrode layer 106 and the second electrode layer 110.

The first electrode layer 106 and the second electrode layer 110 may each independently be formed of conductive material, including metal (e.g., tungsten, titanium, tantalum, ruthenium, cobalt, copper, aluminum, platinum, tin, silver, gold), metallic compound (e.g., tantalum nitride, titanium nitride, tungsten nitride), doped polysilicon, the like, an alloy thereof, or a combination thereof.

The capacitor structures may be arranged side-by-side and may be disposed in a row. It should be noted that the number of the capacitor structures shown in the figures are exemplary only and are not intended to limit the present disclosure. For example, the capacitor die 100a may include more than five capacitor structures.

As shown in FIG. 1, the capacitor die 100a includes a plurality of conductive pillars 104 extending in the semiconductor substrate 102 and electrically coupled to the capacitor structures, in accordance with some embodiments. The capacitor die 100a also includes a plurality of conductive pillars 114 disposed over the capacitor structures and a conductive layer 116 disposed over the conductive pillars 114, in accordance with some embodiments. The conductive pillars 114 may be electrically coupled to the capacitor structures, and the conductive layer 116 may be electrically coupled to the capacitor structures through the conductive pillars 114.

The conductive pillars 104, 114, and the conductive layer 116 may each independently be formed of conductive material, including metal (e.g., tungsten, titanium, tantalum, ruthenium, cobalt, copper, aluminum, platinum, tin, silver, gold), metallic compound (e.g., tantalum nitride, titanium nitride, tungsten nitride), doped polysilicon, the like, an alloy thereof, or a combination thereof.

As illustrated in FIG. 1, the capacitor die 100a includes a dielectric layer 112 disposed over the semiconductor substrate 102, in accordance with some embodiments. The dielectric layer 112 may surround each of the capacitor structures and the conductive pillars 114. The dielectric layer 112 may be formed of dielectric materials, including silicon oxide, silicon nitride, silicon oxynitride, the like, or a combination thereof. The sidewall of the dielectric layer 112 may be substantially coplanar with the sidewall of the semiconductor substrate 102.

As shown in FIG. 1, the DRAM die 100b may be stacked over the capacitor die 100a. The DRAM die 100b includes a die substrate 120, such as a semiconductor material having one or more active devices (not illustrated) formed therein, in accordance with some embodiments. The DRAM die 100b includes a plurality of through vias 122 extending through the die substrate 120, in accordance with some embodiments. The through vias 122 may be formed of conductive material. Examples of conductive materials are described above, and will not be repeated.

The DRAM die 100b includes a die redistribution layer 118 disposed below the die substrate 120, in accordance with some embodiments. The die redistribution layer 118 may include one or more conductive layers disposed in one or more passivation layers. The through vias 122 may be electrically coupled to the capacitor die 100a through the conductive layers of the die redistribution layer 118. The conductive layers may be formed of conductive material. In some embodiments, the passivation layers include a polymer layer, for example, polyimide (PI), polybenzoxazole (PBO), benzocyclobutene (BCB), epoxy, the like, or a combination thereof. Alternatively, the passivation layers may include a dielectric layer, including silicon oxide, silicon nitride, silicon oxynitride, the like, or a combination thereof.

The sidewall of the die redistribution layer 118 may be substantially coplanar with the sidewall of the die substrate 120. The sidewall of the capacitor die 100a may be substantially coplanar with the sidewall of the DRAM die 100b. In particular, the sidewall of the semiconductor substrate 102 of the capacitor die 100a may be substantially coplanar with the sidewall of the die substrate 120 of the DRAM die 100b.

The semiconductor package structure 100 includes a redistribution layer 124 disposed over the DRAM die 100b to electrically couple the DRAM die 100b to the DRAM die 100c, in accordance with some embodiments. The redistribution layer 124 may include the same or similar components as that of the die redistribution layer 118, and will not be repeated. The sidewall of the redistribution layer 124 may be substantially coplanar with the sidewall of the DRAM die 100b and the sidewall of the DRAM die 100c.

The semiconductor package structure 100 includes a plurality of conductive connectors 126 to connect the redistribution layer 124 and the DRAM die 100c. The conductive connectors 126 may include microbumps, controlled collapse chip connection (C4) bumps, solder balls, ball grid array (BGA) balls, bond pads, the like, or a combination thereof.

These DRAM dies 100c and 100d may include the same or similar components as that of the DRAM die 100b, and for the sake of simplicity, those components will not be discussed in detail again. The topmost DRAM die (such as the DRAM die 100d in FIG. 1) may not include the through vias. Three DRAM dies 100b, 100c and 100d are shown for illustrative purposes only, and the semiconductor package structure 100 may include more or fewer than three DRAM dies.

The capacitor die 100a and the DRAM dies 100b, 100c, and 100d may have the same or different thicknesses. For example, the topmost DRAM die (such as the DRAM die 100d in FIG. 1) may have a thickness greater than the thickness of the other dies (such as the capacitor die 100a and the DRAM dies 100b and 100c in FIG. 1).

As shown in FIG. 1, the semiconductor package structure 100 includes a molding material 128 surrounding the capacitor die 100a, the DRAM dies 100b, 100c, and 100d, and the redistribution layer 124, in accordance with some embodiments. The molding material 128 may protect the capacitor die 100a, the DRAM dies 100b, 100c, and 100d, and the redistribution layer 124 from the environment, thereby preventing these components from damage due to, for example, the stress, the chemicals and/or the moisture. The molding material 128 may include a nonconductive material, such as a moldable polymer, an epoxy, a resin, the like, or a combination thereof.

According to the present disclosure, by integrating the capacitor die 100a and the DRAM dies 100b, 100c and 100d, high capacitance of the semiconductor package structure 100 can be achieved, and design flexibility can be increased.

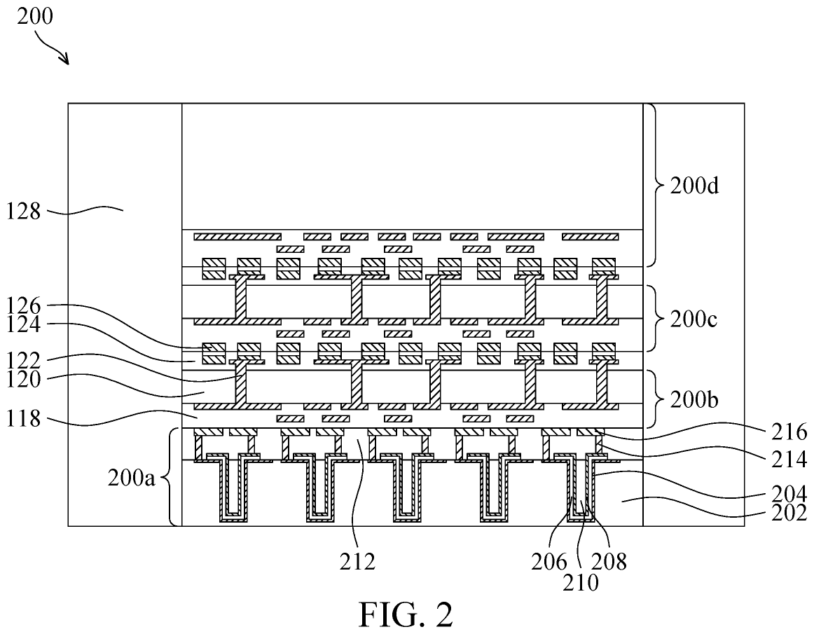

FIG. 2 is a cross-sectional view of a semiconductor package structure 200, in accordance with some embodiments of the disclosure. It should be noted that the semiconductor package structure 200 may include the same or similar components as that of the semiconductor package structure 100, which is illustrated in FIG. 1, and for the sake of simplicity, those components will not be discussed in detail again. In the following embodiments, the semiconductor package structure 200 includes a plurality of deep trench capacitor structures.

As illustrated in FIG. 2, the semiconductor package structure 200 includes a capacitor die 200a, DRAM dies 200b, 200c and 200d, in accordance with some embodiments. The capacitor die 200a may include a semiconductor substrate 202. The semiconductor substrate 202 may be doped. In some embodiments, the semiconductor substrate 202 includes a p-type doped region, which includes p-type dopants, such as boron. Alternatively, the semiconductor substrate 202 includes an n-type doped region, which includes n-type dopants, such as phosphorus, arsenic, or a combination thereof. In some other embodiments, the semiconductor substrate 202 includes more than one doped regions which include different type dopants.

As shown in FIG. 2, the capacitor die 200a includes a plurality of capacitor structure disposed in the semiconductor substrate 202, in accordance with some embodiments. Each of the capacitor structures includes a first electrode layer 204, an interlayer dielectric layer 206, a second electrode layer 208, and a filling material 210, in accordance with some embodiments. As illustrated in FIG. 2, the capacitor structures may be arranged side-by-side and may be disposed in a row.

The capacitor structures may extend from a top surface of the semiconductor substrate 202 to an underlying location within the doped region of the semiconductor substrate 202. In some embodiments, the capacitor structures are deep trench capacitors formed in the trenches. The trenches may be formed by one or more patterning processes, including photolithography processes, etching processes, any suitable processes, or a combination thereof.

The bottom portions of the capacitor structures may have U shapes as shown in FIG. 2, V shapes, or any suitable shapes, depending on the shapes of the trenches. According to some embodiments, the first electrode layer 204, the interlayer dielectric layer 206, and the second electrode layer 208 are formed conformally in the trenches in sequence, and then the filling material 210 is formed in the remaining portion of the trenches and surrounded by the second electrode layer 208.

The first electrode layer 204 and the second electrode layer 208 may each independently formed of conductive materials, and the first electrode layer 204 and the second electrode layer 208 may be formed of the same material or different materials. The interlayer dielectric layer 206 may be formed of silicon oxide, silicon nitride, silicon oxynitride, high-k dielectric materials (e.g., HfO₂, ZrO₂, La₂O₃, Al₂O₃, TiO₂), the like, or a combination thereof. The filling material 210 may be formed of semiconductor materials, including silicon or any suitable materials.

As shown in FIG. 2, the first electrode layer 204 may extend over the top surface of the semiconductor substrate 202. The interlayer dielectric layer 206 may extend over a portion of the top surface of the first electrode layer 204, and end portions of the first electrode layer 204 may be exposed. The second electrode layer 208 may extend over the top surface of the interlayer dielectric layer 206.

In some embodiments, the sidewall of the second electrode layer 208 is substantially coplanar with the sidewall of the interlayer dielectric layer 206. The sidewall of the first electrode layer 204 may extend beyond the sidewall of the interlayer dielectric layer 206 and the sidewall of the second electrode layer 208.

It should be noted that the number of the electrode layers (such as the first electrode layer 204 and the second electrode layer 208) and the number of the interlayer dielectric layer (such as the interlayer dielectric layer 206) shown in the figures are exemplary only and are not intended to limit the present disclosure. For example, the capacitor structures may include additional interlayer dielectric layers and additional electrode layers disposed between the second electrode layer 208 and the filling material 210.

As illustrated in FIG. 2, the capacitor die 200a includes a plurality of conductive pillars 214 disposed over the capacitor structures and a conductive layer 216 disposed over the conductive pillars 214, in accordance with some embodiments. The conductive pillars 214 and the conductive layer 216 may be similar to the conductive pillars 114 and the conductive layer 116 as illustrated in FIG. 1, respectively, and will not be repeated.

The capacitor die 200a includes a dielectric layer 212 disposed over the semiconductor substrate 202 and surrounding the conductive pillars 214, in accordance with some embodiments. The dielectric layer 212 may extend from the top surface of the second electrode layer 208 to the top surface of the first electrode layer 204 and may cover the top surface of the filling material 210 and the sidewall of the interlayer dielectric layer 206. The dielectric layer 212 may be formed of dielectric materials, including silicon oxide, silicon nitride, silicon oxynitride, the like, or a combination thereof. The sidewall of the dielectric layer 212 may be substantially coplanar with the sidewall of the semiconductor substrate 202.

As shown in FIG. 2, the DRAM die 200b, 200c, and 200d may be stacked over the capacitor die 200a. The DRAM die 200b includes a die substrate 120, a plurality of through vias 122 extending through the die substrate 120, and a die redistribution layer 118 disposed below the die substrate 120, in accordance with some embodiments. The die substrate 120, the through vias 122, and the die redistribution layer 118 are described above with respect to FIG. 1, and will not be repeated.

The semiconductor package structure 200 includes a redistribution layer 124 disposed over the DRAM die 200b to electrically couple the DRAM die 200b to the DRAM die 200c, in accordance with some embodiments. The semiconductor package structure 200 includes a plurality of conductive connectors 126 to connect the redistribution layer 124 and the DRAM die 200c. The redistribution layer 124 and the conductive connectors 126 are described above with respect to FIG. 1, and will not be repeated.

According to the present disclosure, by integrating the capacitor die 200a and the DRAM dies 200b, 200c and 200d, high capacitance of the semiconductor package structure 200 can be achieved, and design flexibility can be increased.

The integrated structure of one or more capacitor dies and one or more DRAM dies, such as the semiconductor package structure 100, the semiconductor package structure 200, or a combination thereof, can be used in various structures, and the followings are some examples.

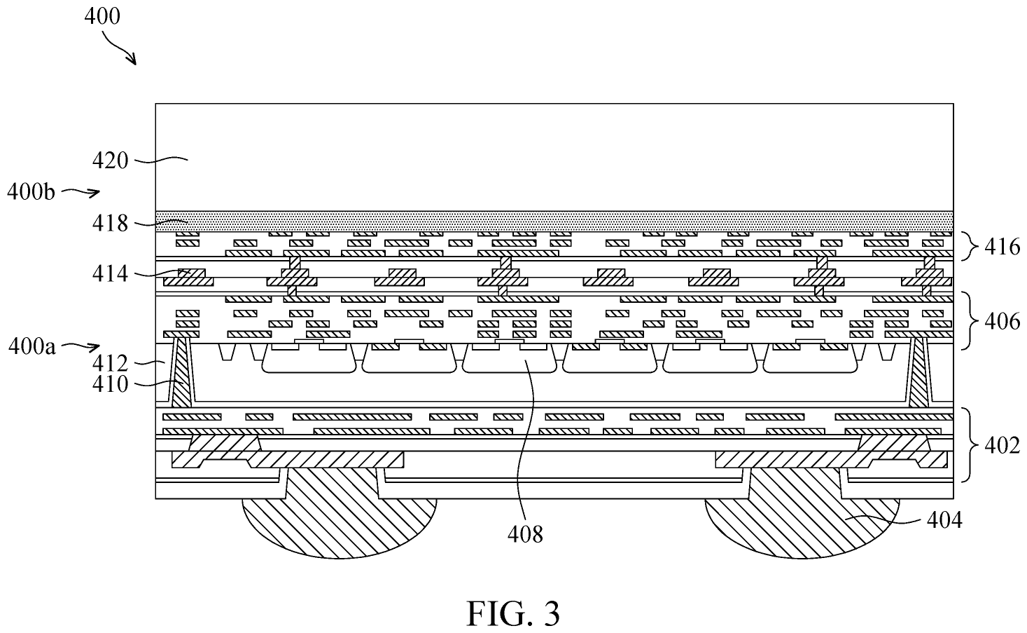

FIG. 3 is a cross-sectional view of a semiconductor package structure 400, in accordance with some embodiments of the disclosure. It should be noted that the semiconductor package structure 400 may include the same or similar components as that of the semiconductor package structure 100 illustrated in FIG. 1, or the semiconductor package structure 200 illustrated in FIG. 2, and for the sake of simplicity, those components will not be discussed in detail again.

As shown in FIG. 3, the semiconductor package structure 400 includes a first package structure 400a and a second package structure 400b stacked vertically, in accordance with some embodiments. The first package structure 400a includes one or more semiconductor dies 408, in accordance with some embodiments. In some embodiments, the semiconductor dies 408 include a system-on-chip (SoC) die, a logic device, a memory device, a radio frequency (RF) device, the like, or a combination thereof. For example, the semiconductor dies 408 may include a micro control unit (MCU) die, a microprocessor unit (MPU) die, a power management integrated circuit (PMIC) die, a global positioning system (GPS) device, an accelerated processing unit (APU) die, a central processing unit (CPU) die, a graphics processing unit (GPU) die, an input-output (TO) die, a dynamic random access memory (DRAM) controller, a static random-access memory (SRAM), a high bandwidth memory (HBM), the like, or a combination thereof.

In some embodiments, the first package structure 400a also includes one or more passive components (not illustrated) adjacent to the semiconductor dies 408, such as resistors, capacitors, inductors, the like, or a combination thereof. It should be noted that the semiconductor dies 408 are shown for illustrative purposes only, and the first package structure 400a may include more or fewer semiconductor dies 408. The semiconductor dies 408 may include the same or different devices.

As illustrated in FIG. 3, the first package structure 400a includes a plurality of conductive pillars 410 adjacent to the semiconductor dies 408, in accordance with some embodiments. The conductive pillars 410 may be formed of conductive materials, including metal (e.g., tungsten, titanium, tantalum, ruthenium, cobalt, copper, aluminum, platinum, tin, silver, gold), metallic compound (e.g., tantalum nitride, titanium nitride, tungsten nitride), doped polysilicon, the like, an alloy thereof, or a combination thereof. The conductive pillars 410 may have tapered sidewalls.

As shown in FIG. 3, the first package structure 400a includes a molding material 412 surrounding the semiconductor dies 408 and the conductive pillars 410, in accordance with some embodiments. The molding material 412 may protect the semiconductor dies 408 and the conductive pillars 410 from the environment, thereby preventing these components from damage due to, for example, the stress, the chemicals and/or the moisture. The molding material 412 may include a nonconductive material, such as a moldable polymer, an epoxy, a resin, the like, or a combination thereof.

As shown in FIG. 3, the first package structure 400a includes a first redistribution layer 402 and a second redistribution layer 406 disposed on opposite sides of the semiconductor dies 408, in accordance with some embodiments. The first redistribution layer 402 and the second redistribution layer 406 may each include one or more conductive layers disposed in one or more passivation layers. The conductive layers may be formed of conductive materials. In some embodiments, the passivation layers include a polymer layer, for example, polyimide (PI), polybenzoxazole (PBO), benzocyclobutene (BCB), epoxy, the like, or a combination thereof. Alternatively, the passivation layers may include a dielectric layer, including silicon oxide, silicon nitride, silicon oxynitride, the like, or a combination thereof.

The semiconductor dies 408 may be disposed below the second redistribution layer 406, and the molding material 412 may extend between the semiconductor dies 408 and the first redistribution layer 402. The conductive pillars 410 may extend through the molding material 412 and may electrically couple the first redistribution layer 402 to the second redistribution layer 406. As shown in FIG. 3, the conductive pillars 410 may have a width decreasing in a direction from the first redistribution layer 402 toward the second redistribution layer 406.

As shown in FIG. 3, the first package structure 400a includes a plurality of bump structures 404 disposed below and electrically coupling to the first redistribution layer 402, in accordance with some embodiments. The bump structures 404 may include microbumps, controlled collapse chip connection (C4) bumps, solder balls, ball grid array (BGA) balls, the like, or a combination thereof. The bump structures 404 may be formed of conductive materials.

The first package structure 400a may be connected to the second package structure 400b through a plurality of conductive connectors 414. The conductive connectors 414 may include microbumps, controlled collapse chip connection (C4) bumps, solder balls, ball grid array (BGA) balls, bond pads, the like, or a combination thereof. The conductive connectors 414 may be formed of conductive materials.

As illustrated in FIG. 3, the second package structure 400b includes a substrate 416, in accordance with some embodiments. The substrate 416 may have a wiring structure disposed in inter-metal dielectric (IMD) layers. In some embodiments, the wiring structure includes conductive pads, conductive vias, conductive lines, conductive pillars, the like, or a combination thereof. The wiring structure may be formed of conductive material. In some embodiments, the IMD layers may be formed of organic materials, such as a polymer base material, non-organic materials, including silicon nitride, silicon oxide, silicon oxynitride, the like, or a combination thereof.

As shown in FIG. 3, the second package structure 400b includes a capacitor die 418 and a DRAM die 420 stacked over the substrate 416 and electrically coupled to the wiring structures of the substrate 416, in accordance with some embodiments. The capacitor die 418 and the DRAM die 420 may be electrically coupled to the semiconductor dies 408 through the wiring structures of the substrate 416 and the second redistribution layer 406. The configurations of the capacitor die 418 and the DRAM die 420 are described above with respect to FIGS. 1 and 2.

In comparison to the capacitor disposed in other place, such as below the first redistribution layer 402, the capacitor die 418 integrated with the DRAM die 420 according to the present disclosure can be electrically coupled to the semiconductor dies 408 through a shorter path. In addition, the size of the capacitor die 418 would not be limited by the size of the package structure 400a, and thus high capacitance of the semiconductor package structure 400 can be achieved, and design flexibility can be increased.

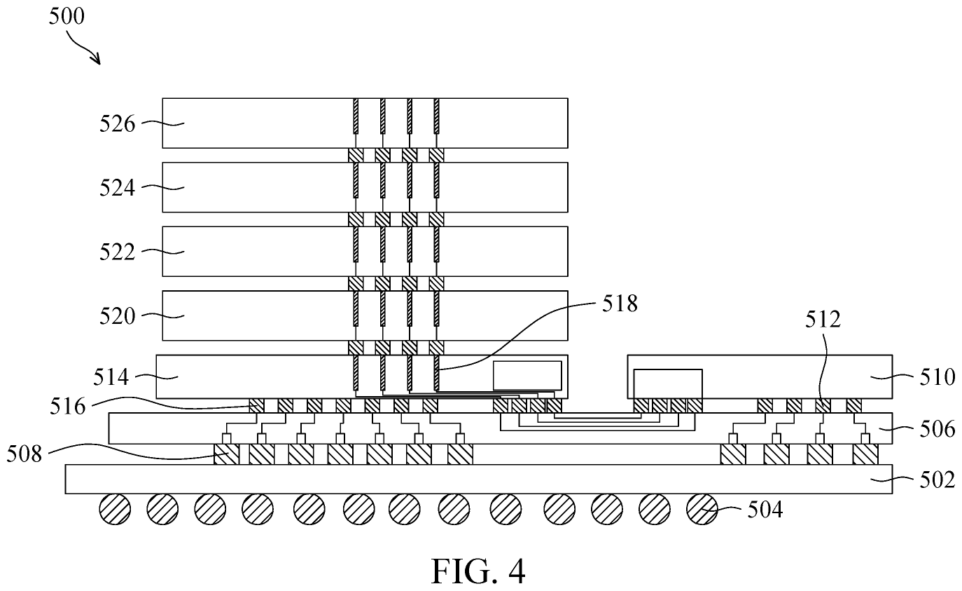

FIG. 4 is a cross-sectional view of a semiconductor package structure 500, in accordance with some embodiments of the disclosure. It should be noted that the semiconductor package structure 500 may include the same or similar components as that of the semiconductor package structure 400, which is illustrated in FIG. 3, and for the sake of simplicity, those components will not be discussed in detail again.

As shown in FIG. 4, the semiconductor package structure 500 includes a package substrate 502, in accordance with some embodiments. The package substrate 502 may have a wiring structure disposed in inter-metal dielectric (IMD) layers. In some embodiments, the wiring structure includes conductive pads, conductive vias, conductive lines, conductive pillars, the like, or a combination thereof. The wiring structure may be formed of conductive material. In some embodiments, the IMD layers may be formed of organic materials, such as a polymer base material, non-organic materials, including silicon nitride, silicon oxide, silicon oxynitride, the like, or a combination thereof.

The semiconductor package structure 500 includes a plurality of bump structures 504 disposed below the package substrate 502 and electrically coupled to the wiring structure of the package substrate 502, in accordance with some embodiments. The bump structures 504 may include microbumps, controlled collapse chip connection (C4) bumps, solder balls, ball grid array (BGA) balls, the like, or a combination thereof. The bump structures 504 may be formed of conductive materials.

As illustrated in FIG. 4, the semiconductor package structure 500 includes an interposer substrate 506 disposed over the package substrate 502, in accordance with some embodiments. The interposer substrate 506 may have a wiring structure disposed in inter-metal dielectric (IMD) layers. The wiring structure of the interposer substrate 506 may be electrically coupled to the wiring structure of the package substrate 502 through a plurality of bump structures 508. The interposer substrate 506 may include the same or similar components as that of the package substrate 502, the bump structures 508 may be similar to the bump structures 504, and will not be repeated.

The semiconductor package structure 500 includes a semiconductor die 510 disposed over the interposer substrate 506, in accordance with some embodiments. The semiconductor die 510 may be electrically coupled to the wiring structure of the interposer substrate 506 through a plurality of bump structures 512. The semiconductor die 510 may include the same or similar components as that of the semiconductor dies 418 as illustrated in FIG. 4, the bump structures 512 may be similar to the bump structures 504, and will not be repeated.

The semiconductor package structure 500 includes a system-on-chip (SoC) die 514 and DRAM dies 520, 522, 524, 526, which are stacked vertically over the interposer substrate 506 and adjacent to the semiconductor die 510, in accordance with some embodiments. The SoC die 514 may include one or more capacitor dies. In some embodiments, the SoC die 514 includes a logic die and a capacitor die. The DRAM dies 520, 522, 524, 526 may each include a memory die and a capacitor die. Four DRAM dies 520, 522, 524, and 526 are shown for illustrative purposes only, and the semiconductor package structure 500 may include more or fewer DRAM dies.

The SoC die 514 and the DRAM dies 520, 522, 524, 526 may be electrically coupled to the interposer substrate 506 through a plurality of bump structures 516 therebetween and a plurality of through vias 518 therein, and may be electrically coupled to the semiconductor die 510 through the bump structures 516 and the interposer substrate 506. The bump structures 516 may be similar to the bump structures 512, the through vias 518 may be similar to the through vias 122 as illustrated in FIG. 1, and will not be repeated.

The semiconductor package structure 500 may further include a molding material (not illustrated) surrounding the SoC die 514 and the DRAM dies 520, 522, 524, 526, in accordance with some embodiments. The molding material may protect the SoC die 514 and the DRAM dies 520, 522, 524, 526 from the environment, thereby preventing these components from damage due to, for example, the stress, the chemicals and/or the moisture. The molding material may include a nonconductive material, such as a moldable polymer, an epoxy, a resin, the like, or a combination thereof.

By integrating the DRAM dies 520, 522, 524, 526, which include a memory die and a capacitor die, high capacitance of the semiconductor package structure 500 can be achieved, and design flexibility can be increased.

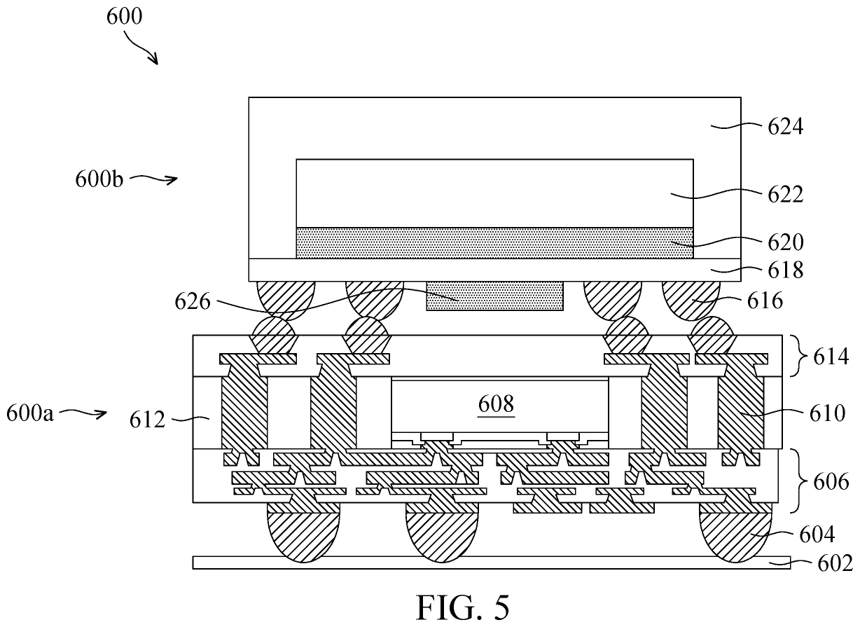

FIG. 5 is a cross-sectional view of a semiconductor package structure 600, in accordance with some embodiments of the disclosure. It should be noted that the semiconductor package structure 600 may include the same or similar components as that of the semiconductor package structure 400, which is illustrated in FIG. 3, and for the sake of simplicity, those components will not be discussed in detail again.

As shown in FIG. 5, the semiconductor package structure 600 includes a first package structure 600a and a second package structure 600b stacked vertically over a substrate 602, in accordance with some embodiments. The substrate 602 may have a wiring structure disposed in inter-metal dielectric (IMD) layers. In some embodiments, the wiring structure includes conductive pads, conductive vias, conductive lines, conductive pillars, the like, or a combination thereof. The wiring structure may be formed of conductive material. In some embodiments, the IMD layers may be formed of organic materials, such as a polymer base material, non-organic materials, including silicon nitride, silicon oxide, silicon oxynitride, the like, or a combination thereof.

The first package structure 600a includes a first redistribution layer 606 disposed over the substrate 602 and electrically coupled to the substrate 602 through a plurality of bump structures 604, in accordance with some embodiments. The bump structures 604 may be similar to the bump structures 404 as illustrated in FIG. 3, and will not be repeated.

The first redistribution layer 606 may include one or more conductive layers disposed in one or more passivation layers. The conductive layers may be formed of conductive materials. In some embodiments, the passivation layers include a polymer layer, for example, polyimide (PI), polybenzoxazole (PBO), benzocyclobutene (BCB), epoxy, the like, or a combination thereof. Alternatively, the passivation layers may include a dielectric layer, including silicon oxide, silicon nitride, silicon oxynitride, the like, or a combination thereof.

The first package structure 600a includes a semiconductor die 608 disposed over the first redistribution layer 606, in accordance with some embodiments. In some embodiments, the semiconductor die 608 includes a system-on-chip (SoC) die, a logic device, a memory device, a radio frequency (RF) device, the like, or a combination thereof. For example, the semiconductor die 608 may include a micro control unit (MCU) die, a microprocessor unit (MPU) die, a power management integrated circuit (PMIC) die, a global positioning system (GPS) device, an accelerated processing unit (APU) die, a central processing unit (CPU) die, a graphics processing unit (GPU) die, an input-output (IO) die, a dynamic random access memory (DRAM) controller, a static random-access memory (SRAM), a high bandwidth memory (HBM), the like, or a combination thereof.

In some embodiments, the first package structure 600a includes one or more passive components (not illustrated) adjacent to the semiconductor die 608, such as resistors, capacitors, inductors, the like, or a combination thereof. In addition, the first package structure 600a may include more than one semiconductor die 608.

The first package structure 600a includes a plurality of conductive pillars 610 adjacent to the semiconductor die 608, in accordance with some embodiments. The conductive pillars 610 may be formed of conductive materials. The first package structure 600a includes a molding material 612 surrounding the semiconductor die 608 and the conductive pillars 610, in accordance with some embodiments. The molding material 612 may protect the semiconductor die 608 and the conductive pillars 610 from the environment, thereby preventing these components from damage due to, for example, the stress, the chemicals and/or the moisture. In some embodiments, the molding material 612 includes a nonconductive material, such as a moldable polymer, an epoxy, a resin, the like, or a combination thereof.

As shown in FIG. 5, the first package structure 600a includes a second redistribution layer 614 disposed over the semiconductor die 608 and covering the molding material 612, in accordance with some embodiments. The conductive pillars 610 may extend through the molding material 612 and electrically couple the first redistribution layer 606 to the second redistribution layer 614. The second redistribution layer 614 may include the same or similar components as that of the first redistribution layer 606, and will not be repeated.

The first package structure 600a may be connected to the second package structure 600b through a plurality of conductive connectors 616. The conductive connectors 616 may include microbumps, controlled collapse chip connection (C4) bumps, solder balls, ball grid array (BGA) balls, bond pads, the like, or a combination thereof. The conductive connectors 616 may be formed of conductive materials.

As illustrated in FIG. 5, the second package structure 600b includes a substrate 618, in accordance with some embodiments. The substrate 618 may have a wiring structure disposed in inter-metal dielectric (IMD) layers. In some embodiments, the wiring structure includes conductive pads, conductive vias, conductive lines, conductive pillars, the like, or a combination thereof. The wiring structure may be formed of conductive material. In some embodiments, the IMD layers may be formed of organic materials, such as a polymer base material, non-organic materials, including silicon nitride, silicon oxide, silicon oxynitride, the like, or a combination thereof.

The second package structure 600b includes a capacitor die 620 and a DRAM die 622 stacked over the substrate 618 and electrically coupled to the wiring structures of the substrate 618, in accordance with some embodiments. The capacitor die 620 and the DRAM die 622 may be electrically coupled to the semiconductor die 608 through the wiring structures of the substrate 618 and the second redistribution layer 614. The configurations of the capacitor die 620 and the DRAM die 622 are described above with respect to FIGS. 1 and 2.

The second package structure 600b includes a molding material 624 disposed over the substrate 618, in accordance with some embodiments. The molding material 624 may surround the capacitor die 620 and the DRAM die 622 and cover the top surface of the DRAM die 622, thereby preventing these components from damage due to, for example, the stress, the chemicals and/or the moisture. The molding material 624 may include a nonconductive material, such as a moldable polymer, an epoxy, a resin, the like, or a combination thereof.

The second package structure 600b may further include a capacitor structure 626 disposed below the substrate 618 and electrically coupled to the wiring structures of the substrate 618.

By integrating the capacitor die 620 and the DRAM die 622, high capacitance of the semiconductor package structure 600 can be achieved, and design flexibility can be increased.

In summary, the semiconductor package structure according to the present disclosure includes integrated capacitor die and DRAM dies. The capacitor die includes a plurality of capacitor structures. Therefore, high capacitance of the semiconductor package structure can be achieved, and design flexibility can be increased.

Moreover, according to some embodiments, the integrated capacitor die and DRAM dies make the capacitor die be electrically coupled to the semiconductor die through a shorter path. In addition, the size of the capacitor die would not be limited by the size of the semiconductor package structure, thereby further increasing the capacitance of the semiconductor package structure.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package structure, comprising:
a dynamic random access memory (DRAM) die;
a capacitor die disposed below the DRAM die and comprising:
a plurality of capacitor structures arranged side-by-side; and
a plurality of first conductive pillars disposed over the plurality of capacitor structures and electrically coupled to the DRAM die; and
a molding material surrounding the capacitor die and the DRAM die.

2. The semiconductor package structure as claimed in claim 1, wherein the capacitor die further comprises:
a semiconductor substrate, wherein the plurality of capacitor structures are disposed over the semiconductor substrate; and
a dielectric layer disposed over the semiconductor substrate and surrounding the plurality of capacitor structures and the plurality of first conductive pillars.

3. The semiconductor package structure as claimed in claim 2, wherein each of the capacitor structures comprises:
a first electrode layer;
capacitor cells disposed over the first electrode layer; and
a second electrode layer disposed over the capacitor cells.

4. The semiconductor package structure as claimed in claim 3, wherein the capacitor die further comprises a plurality of second conductive pillars extending through the semiconductor substrate and electrically coupled to the first electrode layer.

5. The semiconductor package structure as claimed in claim 1, wherein the capacitor die comprises:
a semiconductor substrate, wherein the plurality of capacitor structures extend into the semiconductor substrate; and
a dielectric layer covering the plurality of capacitor structures and surrounding the plurality of first conductive pillars.

6. The semiconductor package structure as claimed in claim 5, wherein the capacitor structures comprise a first electrode layer, an interlayer dielectric layer, a second electrode layer, and a filling material.

7. The semiconductor package structure as claimed in claim 1, wherein the DRAM die comprises a die redistribution layer electrically coupled to the plurality of first conductive pillars.

8. The semiconductor package structure as claimed in claim 1, further comprising another DRAM die disposed over and electrically coupled to the DRAM die.

9. A semiconductor package structure, comprising:
a substrate comprising a wiring structure;
a capacitor die disposed over the substrate and comprising a plurality of capacitor structures;
a dynamic random access memory (DRAM) die stacked over and electrically coupled to the capacitor die;
a first molding material disposed over the substrate and surrounding the capacitor die and the DRAM die; and
a semiconductor die electrically coupled to the capacitor die and the DRAM die through the wiring structure of the substrate.

10. The semiconductor package structure as claimed in claim 9, wherein the capacitor die and the DRAM die are stacked over a first surface of the substrate, and the semiconductor die is disposed below a second surface of the substrate, wherein the second surface is opposite to the first surface.

11. The semiconductor package structure as claimed in claim 10, further comprising a first redistribution layer disposed between the semiconductor die and the substrate and electrically coupling the semiconductor die to the wiring structure of the substrate.

12. The semiconductor package structure as claimed in claim 11, further comprising:
a second molding material surrounding the semiconductor die;
a second redistribution layer disposed below the second molding material; and
a conductive pillar extending through the second molding material and electrically coupling the first redistribution layer to the second redistribution layer.

13. The semiconductor package structure as claimed in claim 9, wherein the capacitor die and the DRAM die are stacked over a first surface of the substrate, and the semiconductor die is disposed over the first surface of the substrate and adjacent to the capacitor die.

14. The semiconductor package structure as claimed in claim 13, further comprising a package substrate disposed below a second surface of the substrate and electrically coupled to the wiring structure of the substrate, wherein the second surface is opposite to the first surface.

15. The semiconductor package structure as claimed in claim 13, wherein the substrate comprises an interposer substrate.

16. A semiconductor package structure, comprising:
a first package structure comprising a semiconductor die;
a second package structure stacked over the first package structure and comprising:
a substrate;
a capacitor die disposed over the substrate and electrically coupled to the semiconductor die, wherein the capacitor die comprises a plurality of capacitor structures arranged side-by-side; and
a first dynamic random access memory (DRAM) die electrically coupled to the semiconductor die through the capacitor die.

17. The semiconductor package structure as claimed in claim 16, wherein the first package structure further comprises a first redistribution layer and a second redistribution layer disposed on opposite sides of the semiconductor die and electrically coupled to the semiconductor die.

18. The semiconductor package structure as claimed in claim 16, wherein the second package structure further comprises:
a second DRAM die disposed over the first DRAM die; and
a molding material surrounding the capacitor die, the first DRAM die, and the second DRAM die.

19. The semiconductor package structure as claimed in claim 18, wherein the first DRAM die comprises a first through via electrically coupled to the second DRAM die.

20. The semiconductor package structure as claimed in claim 16, wherein the second package structure further comprises an additional capacitor structure disposed below the substrate and electrically coupled to the semiconductor die.
